(19) United States
(12) Patent Application Publication
(10) Pub. No.: US 2025/0374649 A1
(43) Pub. Date: Dec. 4, 2025

(54) SEMICONDUCTOR DEVICE AND VEHICLE

(71) Applicant: Rohm Co., Ltd., Kyoto-shi (JP)

(72) Inventor: Hidetoshi ABE, Kyoto-shi (JP)

(21) Appl. No.: 19/298,853

(22) Filed: Aug. 13, 2025

Related U.S. Application Data
(63) Continuation of application No. PCT/JP2024/002597, filed on Jan. 29, 2024.

(30) Foreign Application Priority Data
Feb. 20, 2023 (JP) 2023-024454

(51) Int. Cl. H10D 80/20; B60L 15/00; H01L 23/00; H01L 23/31; H01L 23/373; H01L 25/07

(52) U.S. Cl. CPC H10D 80/251; H01L 23/3107; H01L 23/3735; H01L 24/32; H01L 24/48; H01L 24/73; H01L 25/072; B60L 15/007; H01L 2224/32225; H01L 2224/48175; H01L 2224/73265; H01L 2924/10272; H01L 2924/13091

(57) ABSTRACT

A semiconductor device includes: a conductive layer including a mounting surface; a first semiconductor element bonded to the mounting surface; a first terminal electrically connected to the first semiconductor element; and a first bonding layer electrically bonding the conductive layer and the first terminal. The conductive layer includes a first end surface, and a first peripheral surface located inward of the conductive layer from the first end surface as viewed in a first direction. The conductive layer includes a first engagement portion defined by the first peripheral surface. The first terminal includes a first bonding portion electrically bonded to the first engagement portion via the first bonding layer. As viewed in the first direction, the first bonding portion overlaps with the first engagement portion.

### TECHNICAL FIELD

The present disclosure relates to a semiconductor device and a vehicle equipped with the semiconductor device.

### BACKGROUND ART

JP-A-2016-192450 discloses an example of a semiconductor device featuring a MOSFET. The semiconductor device includes a drain terminal to which a power supply voltage is applied, a gate terminal that receives an input electrical signal for the MOSFET, and a source terminal that outputs the power resulting from the conversion of the supplied power, which corresponds to the power supply voltage, based on the electrical signal. The MOSFET includes a drain electrode electrically connected to the drain terminal, and a source electrode electrically connected to the source terminal, and a gate electrode electrically connected to the gate terminal. The drain electrode is electrically bonded to a die pad (tab). The drain terminal is integral with the die pad. The source electrode is electrically bonded to a metal clip, which is electrically bonded to the source terminal. This allows the semiconductor device to carry a larger electric current.

In a configuration different from the semiconductor device of JP-A-2016-192450, the drain terminal may be electrically bonded to the die pad via a conductive bonding material, such as solder. In this configuration, misalignment of the drain terminal with the die pad is possible, and the degree of misalignment tends to increase with the size of the drain terminal. A greater degree of misalignment can lead to a reduced bonding area between the drain terminal and the die pad. This can consequently reduce the amount of current the semiconductor device can handle.

### BRIEF DESCRIPTION OF THE DRAWINGS

FIG. 1 is a plan view of a semiconductor device according to a first embodiment of the present disclosure.

FIG. 2 is a plan view corresponding to FIG. 1, with a sealing resin shown as transparent.

FIG. 3 is a bottom view of the semiconductor device shown in FIG. 1.

FIG. 4 is a right-side view of the semiconductor device shown in FIG. 1.

FIG. 5 is a sectional view taken along line V-V in FIG. 2.

FIG. 6 is a sectional view taken along line VI-VI in FIG. 2.

FIG. 7A is a partially enlarged view of FIG. 5, showing a portion around a first semiconductor element.

FIG. 7B is a partially enlarged view of FIG. 5, showing a portion around a second semiconductor element.

FIG. 8 is a partially enlarged view of FIG. 2.

FIG. 9 is a sectional view taken along line IX-IX in FIG. 8.

FIG. 10 is a partially enlarged sectional view of a semiconductor device according to a first variation of the first embodiment of the present disclosure.

FIG. 11 is a partially enlarged sectional view of a semiconductor device according to a second variation of the first embodiment of the present disclosure.

FIG. 12 is a partially enlarged sectional view of a semiconductor device according to a third variation of the first embodiment of the present disclosure.

FIG. 13 is a partially enlarged sectional view of a semiconductor device according to a fourth variation of the first embodiment of the present disclosure.

FIG. 14 is a schematic diagram of a vehicle equipped with the semiconductor device shown in FIG. 1.

FIG. 15 is a plan view of a semiconductor device according to a second embodiment of the present disclosure, with a sealing resin shown as transparent.

FIG. 16 is a sectional view taken along line XVI-XVI in FIG. 15.

FIG. 17 is a sectional view taken along line XVII-XVII in FIG. 15.

FIG. 18 is a partially enlarged view of FIG. 15.

FIG. 19 is a sectional view taken along line XIX-XIX in FIG. 18.

### DETAILED DESCRIPTION OF EMBODIMENTS

The following describes embodiments of the present disclosure, with reference to the accompanying drawings.

### First Embodiment

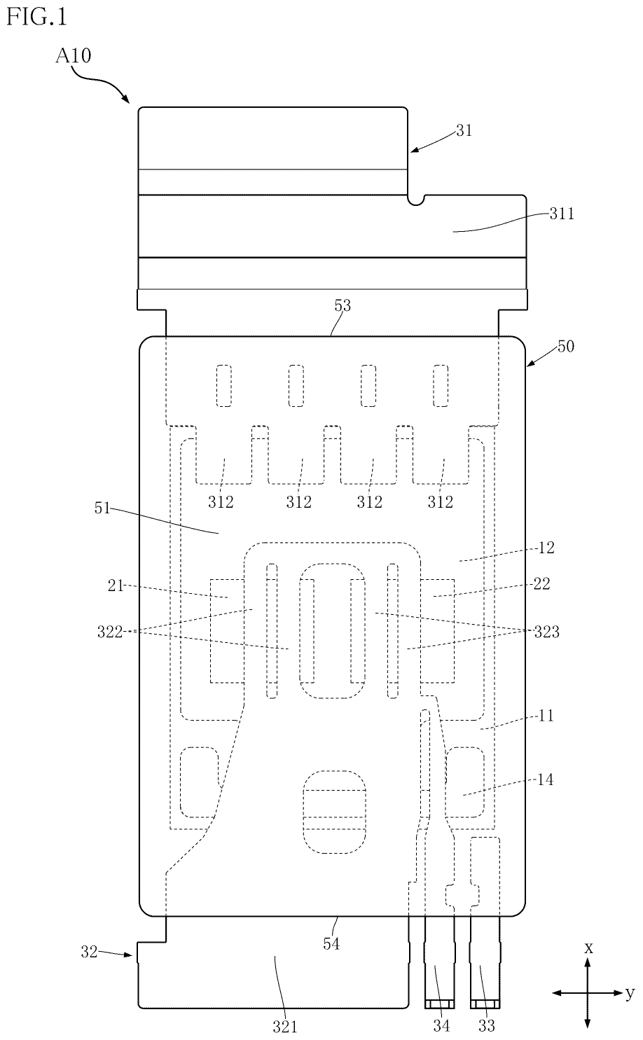

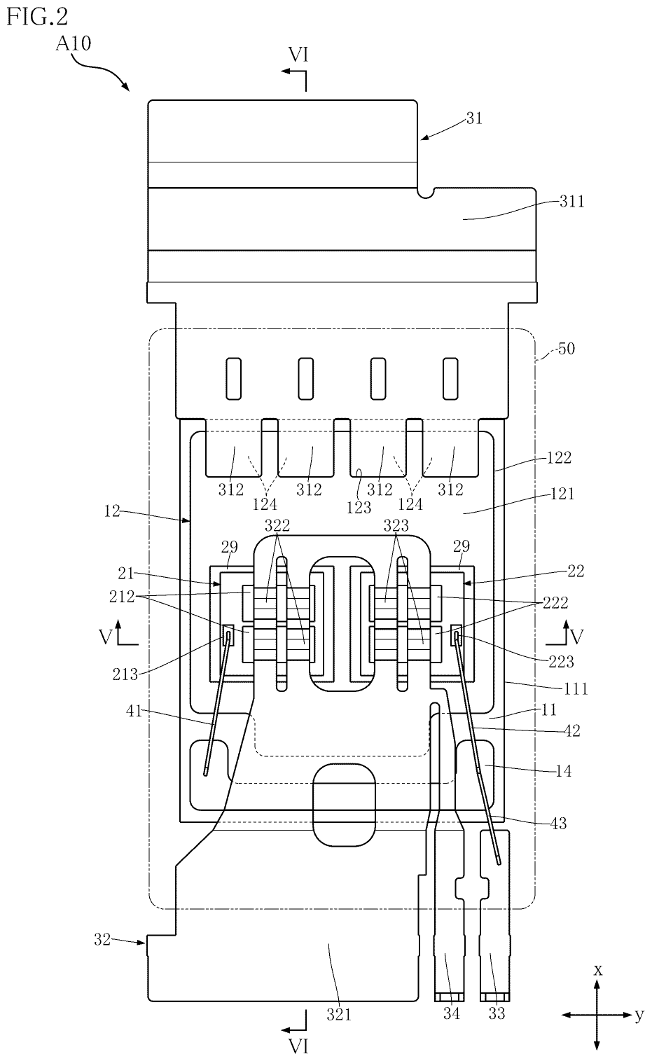

With reference to FIGS. 1 to 9, the following describes a semiconductor device A10 according to a first embodiment of the present disclosure. The semiconductor device A10 is typically used for a power conversion circuit, such an inverter. The semiconductor device A10 includes an insulating layer 11, a conductive layer 12, a heat dissipation layer 13, a first wiring layer 14, a first semiconductor element 21, a second semiconductor element 22, a first terminal 31, a second terminal 32, a first signal terminal 33, a second signal terminal 34, a first bonding layer 38, and a sealing resin 50. The semiconductor device A10 additionally includes a first conductive member 41, a second conductive member 42, and a third conductive member 43. For convenience, FIG. 2 shows the sealing resin 50 as transparent. The outline of the sealing resin 50 is indicated by imaginary lines (dash-double-dot lines) in FIG. 2.

For convenience in the description of the semiconductor device A10, the direction of the normal to a later-described mounting surface 121 of the conductive layer 12, for example, is referred to as “first direction z.” A direction perpendicular to the first direction z is referred to as “second direction x”. The direction perpendicular to the first direction z and the second direction x is referred to as “third direction y”.

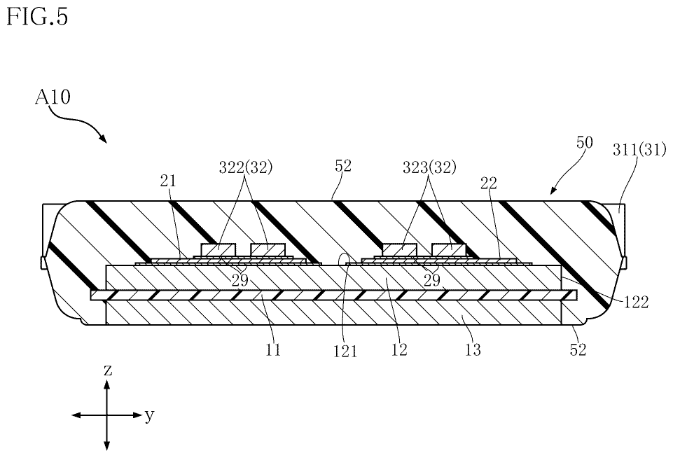

As shown in FIG. 5, the sealing resin 50 covers the first semiconductor element 21 and the second semiconductor element 22. The sealing resin 50 is an insulator. The sealing resin 50 is made of a material, including a black epoxy resin, for example.

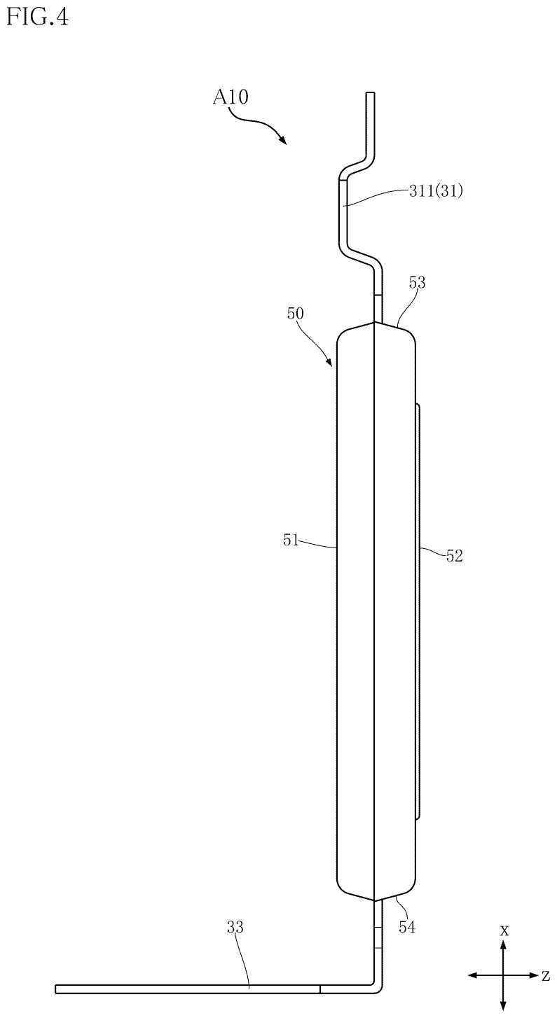

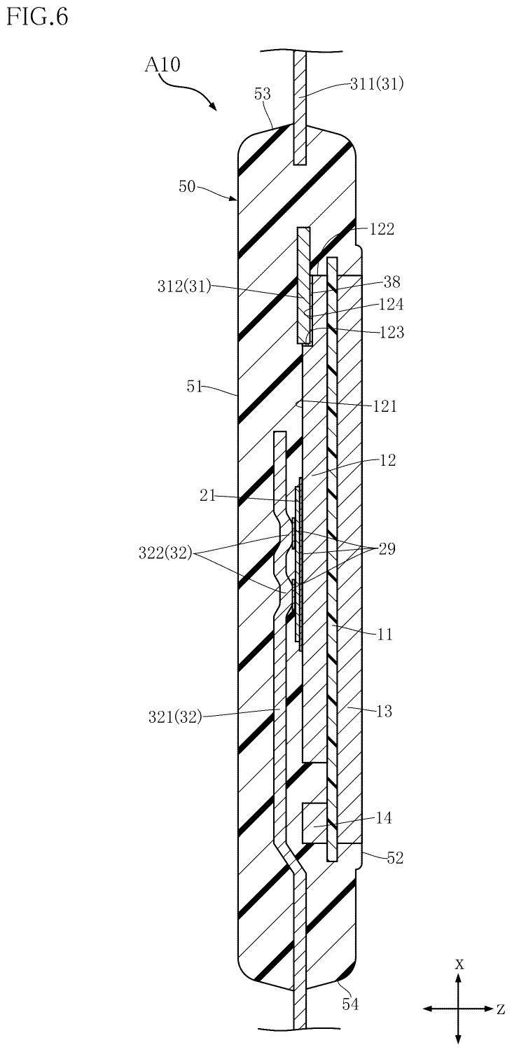

As shown in FIG. 4, the sealing resin 50 has a top surface 51, a bottom surface 52, a first side surface 53, and a second side surface 54. As shown in FIGS. 5 and 6, the top surface 51 faces the same side as the later-described mounting surface 121 of the conductive layer 12 in the first direction z. The bottom surface 52 faces away from the top surface 51 in the first direction z.

As shown in FIGS. 1, 3, and 4, the first side surface 53 and the second side surface 54 face away from each other in the second direction x. The first side surface 53 and the second side surface 54 are each connected to the top surface 51 and the bottom surface 52.

As shown in FIGS. 5 and 6, the insulating layer 11 is covered with the sealing resin 50. The insulating layer 11 is made of a material with a relatively high thermal conductivity. For example, the insulating layer 11 is made of a ceramic material containing either silicon nitride (Si₃N₄) or aluminum nitride (AlN). In another example, the insulating layer 11 may be made of a material, including resin.

As shown in FIGS. 5 and 6, the conductive layer 12 is bonded to one side of the insulating layer 11 in the first direction z. The conductive layer 12 is where the first semiconductor element 21 and the second semiconductor element 22 are mounted. As viewed in the first direction z, the conductive layer 12 is enclosed within the periphery 111 of the insulating layer 11. The conductive layer 12 is covered with the sealing resin 50. The conductive layer 12 contains copper (Cu). The dimension of the conductive layer 12 in the first direction z is larger than the dimension of the insulating layer 11 in the first direction z.

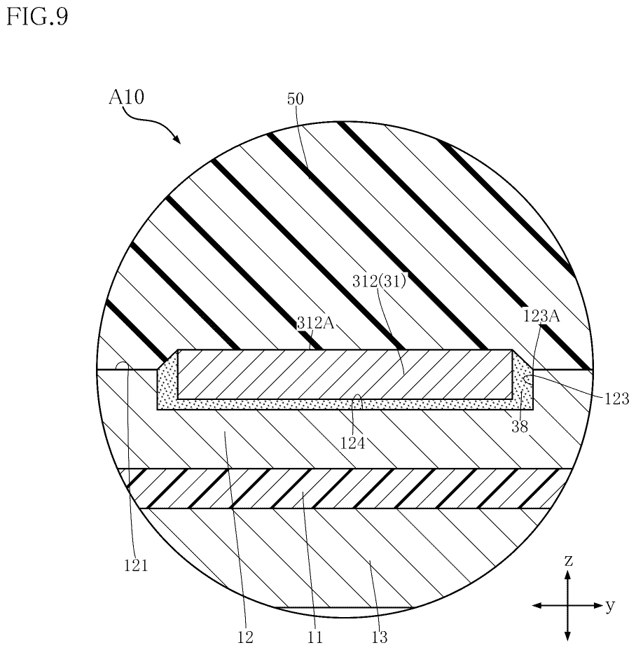

As shown in FIGS. 2 and 5, the conductive layer 12 has the mounting surface 121, the first end surface 122, and a plurality of first peripheral surfaces 123. The mounting surface 121 faces one side in the first direction z. The first semiconductor element 21 and the second semiconductor element 22 face in a direction of the mounting surface 121. The first end surface 122 faces in a direction perpendicular to the first direction z. The first end surface 122 is connected to the mounting surface 121. Each first peripheral surface 123 faces in a direction perpendicular to the first direction z and is located inward of the conductive layer 12 from the first end surface 122 as viewed in the first direction z. The first peripheral surfaces 123 are next to each other in the third direction y. As shown in FIG. 9, each first peripheral surface 123 has a first upper edge 123A. The first upper edge 123A is a boundary between the first peripheral surface 123 and the mounting surface 121.

As shown in FIGS. 6 and 9, the conductive layer 12 is provided with a plurality of first engagement portions 124. Each first engagement portion 124 is defined by a first peripheral surface 123. In the semiconductor device A10, each first engagement portion 124 is a recess that is recessed from the mounting surface 121.

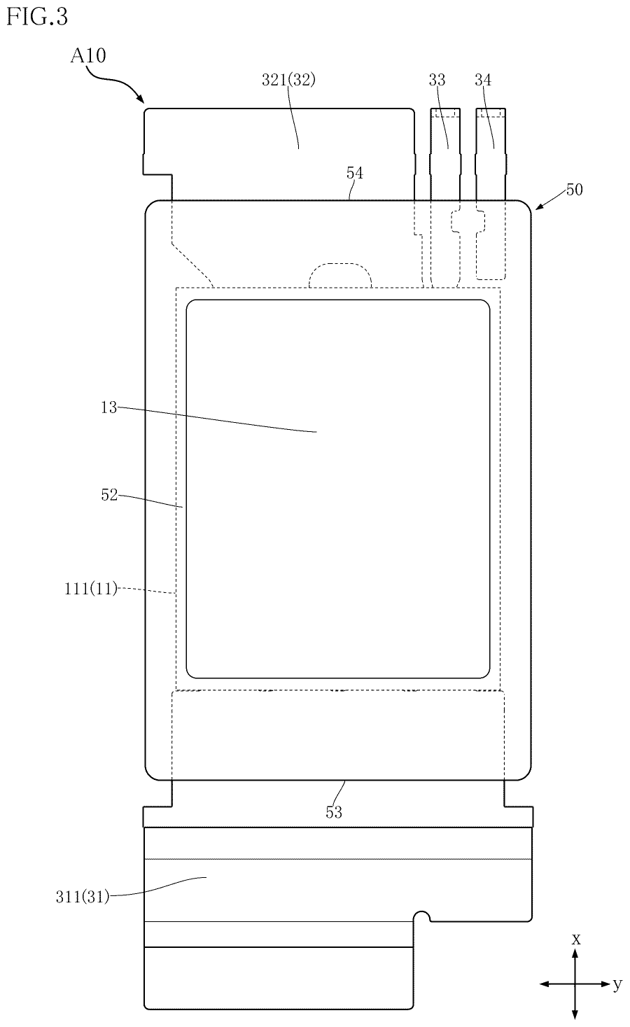

As shown in FIGS. 5 and 6, the heat dissipation layer 13 is located on the opposite side of the insulating layer 11 from the conductive layer 12 and is bonded to the insulating layer 11. As viewed in the first direction z, the heat dissipation layer 13 is enclosed within the periphery 111 of the insulating layer 11, overlapping with the conductive layer 12. As shown in FIG. 3, the heat dissipation layer 13 is exposed to the outside from the bottom surface 52 of the sealing resin 50. The heat dissipation layer 13 contains copper. In the semiconductor device A10, the dimension of the heat dissipation layer 13 in the first direction z is larger than the dimension of the insulating layer 11 in the first direction z, and is equal to the dimension of the conductive layer 12 in the first direction z. Alternatively, the dimension of the heat dissipation layer 13 in the first direction z relative to the dimensions of the insulating layer 11 and the conductive layer 12 in the first direction z may be different from the example.

As shown in FIGS. 2 and 6, the first wiring layer 14 is located on the same side as the conductive layer 12 with respect to the insulating layer 11 and is bonded to the insulating layer 11. The first wiring layer 14 is adjacent to the conductive layer 12 in the second direction x. The first wiring layer 14 extends in the third direction y. As viewed in the first direction z, the first wiring layer 14 is enclosed within the periphery 111 of the insulating layer 11. The first wiring layer 14 is covered with the sealing resin 50. The first wiring layer 14 contains copper. The dimension of the first wiring layer 14 in the first direction z is larger than the dimension of the insulating layer 11 in the first direction z.

As shown in FIGS. 5 and 6, the first semiconductor element 21 is bonded to the mounting surface 121 of the conductive layer 12. The first semiconductor element 21 is a metal-oxide-semiconductor field-effect transistor (MOSFET), for example. In other examples, the first semiconductor element 21 may be a field effect transistor, such as metal-insulator-semiconductor field-effect transistor (MISFET), or a bipolar transistor, such as an insulated gate bipolar transistor (IGBT). In the description of the semiconductor device A10 below, the first semiconductor element 21 is an n-channel vertical MOSFET. The first semiconductor element 21 includes a compound semiconductor substrate. The compound semiconductor substrate contains silicon carbide (SiC) in its composition.

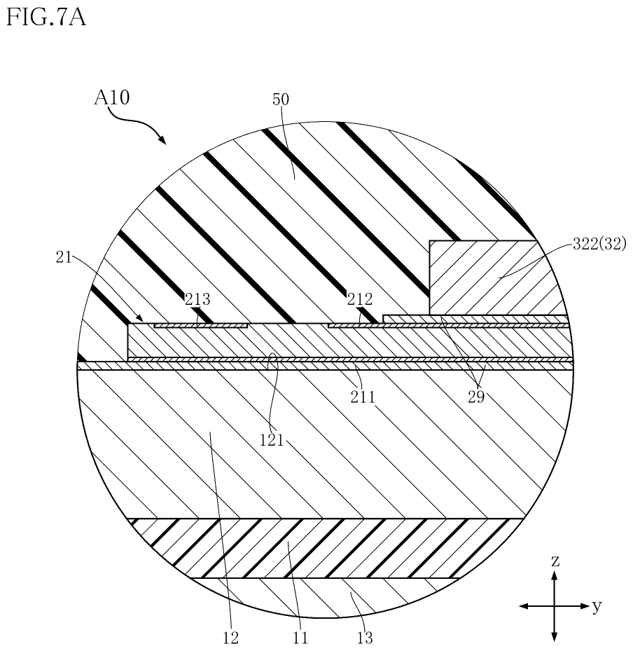

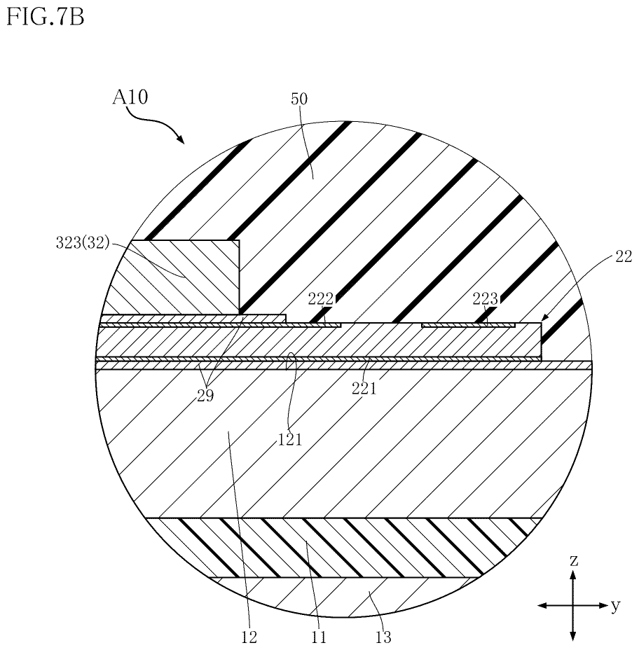

As shown in FIG. 7A, the first semiconductor element 21 includes a first electrode 211, two second electrodes 212, and a first gate electrode 213.

As shown in FIG. 7A, the first electrode 211 is located on one side in the first direction z. The first electrode 211 faces in the direction of the mounting surface 121 of the conductive layer 12. The first electrode 211 is electrically bonded to the mounting surface 121 via a conductive bonding layer 29. This electrically connects the first electrode 211 to the conductive layer 12. The conductive bonding layer 29 is solder, for example. In other examples, the conductive bonding layer 29 may be sintered metal, such as silver. The first electrode 211 is where the electric current corresponding to the power to be modulated by the first semiconductor element 21 flows. In short, the first electrode 211 is the drain of the first semiconductor element 21.

As shown in FIG. 7A, the two second electrodes 212 are disposed on the opposite side from the first electrode 211 in the first direction z. As shown in FIG. 2, the two second electrodes 212 are spaced apart from each other in the second direction x. Each of the two second electrodes 212 is where the electric current corresponding to the power modulated by the first semiconductor element 21 flows. In short, the two second electrodes 212 are the source of the first semiconductor element 21.

As shown in FIGS. 2 and 7A, the first gate electrode 213 is located on the same side as the two second electrodes 212 in the first direction z. The first gate electrode 213 is where the gate voltage for controlling the first semiconductor element 21 is applied. The first gate electrode 213 is electrically connected to the first wiring layer 14. As shown in FIG. 2, the first gate electrode 213 is smaller in area than each second electrode 212 as viewed in the first direction z.

As shown in FIG. 5, the second semiconductor element 22 is bonded to the mounting surface 121 of the conductive layer 12. The second semiconductor element 22 is identical to the first semiconductor element 21. Thus, the second semiconductor element 22 is also an n-channel vertical MOSFET. The second semiconductor element 22 is adjacent to the first semiconductor element 21 in the third direction y.

As shown in FIG. 7B, the second semiconductor element 22 includes a third electrode 221, two fourth electrodes 222, and a second gate electrode 223.

As shown in FIG. 7B, the third electrode 221 is located on one side in the first direction z. The third electrode 221 faces in the direction of the mounting surface 121 of the conductive layer 12. The third electrode 221 is electrically bonded to the mounting surface 121 via a conductive bonding layer 29. This electrically connects the third electrode 221 to the conductive layer 12. The third electrode 221 is where the electric current corresponding to the power to be modulated by the second semiconductor element 22 flows. In short, the third electrode 221 is the drain of the second semiconductor element 22.

As shown in FIG. 7B, the two fourth electrodes 222 are disposed on the opposite side from the third electrode 221 in the first direction z. As shown in FIG. 2, the two fourth electrodes 222 are spaced apart from each other in the second direction x. Each of the two fourth electrodes 222 is where the electric current corresponding to the power modulated by the second semiconductor element 22 flows. In short, the two fourth electrodes 222 are the source of the second semiconductor element 22.

As shown in FIGS. 2 and 7B, the second gate electrode 223 is located on the same side as the two fourth electrodes 222 in the first direction z. The second gate electrode 223 is where the gate voltage for controlling the second semiconductor element 22 is applied. The second gate electrode 223 is electrically connected to the first wiring layer 14. As shown in FIG. 2, the second gate electrode 223 is smaller in area than each fourth electrode 222 as viewed in the first direction Z.

As shown in FIG. 2, the first terminal 31 is located on one side in the second direction x from the first semiconductor element 21 and the second semiconductor element 22. The first terminal 31 is electrically connected to the first electrode 211 of the first semiconductor element 21 and the third electrode 221 of the second semiconductor element 22. Thus, the first terminal 31 is the drain terminal of the semiconductor device A10. The first terminal 31 contains copper.

As shown in FIGS. 2 and 6, the first terminal 31 has a first base portion 311 and a plurality of first bonding portions 312. The first base portion 311 is spaced apart from the mounting surface 121 of the conductive layer 12 as viewed in the first direction z. As shown in FIG. 1, the first base portion 311 includes a portion covered with the sealing resin 50 and a portion exposed to the outside from the first side surface 53 of the sealing resin 50. As viewed in first direction z, the first bonding portions 312 extend from the first base portion 311 in the second direction x toward the first semiconductor element 21 and the second semiconductor element 22. The first bonding portions 312 are next to each other in the third direction y. The first bonding portions 312 are covered with the sealing resin 50. As viewed in the first direction z, the first bonding portions 312 overlap with the respective first engagement portions 124 of the conductive layer 12.

As shown in FIG. 9, the first bonding layer 38 electrically bonds each first engagement portion 124 of the conductive layer 12 and a corresponding first bonding portion 312 of the first terminal 31. This electrically connects the first terminal 31 to the first electrode 211 of the first semiconductor element 21 and the third electrode 221 of the second semiconductor element 22. The first bonding layer 38 is solder, for example.

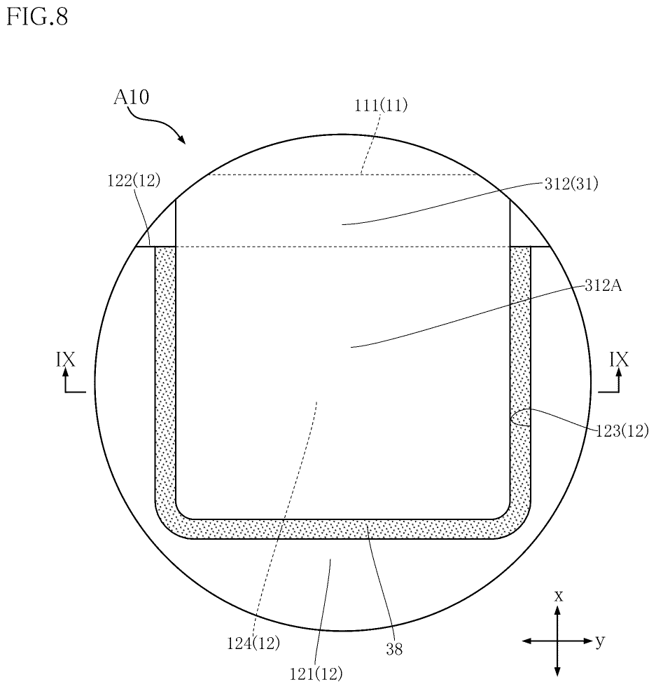

As shown in FIG. 9, each first bonding portion 312 of the first terminal 31 is at least partially accommodated in the corresponding first engagement portion 124 of the conductive layer 12. The first bonding layer 38 is in contact with each first peripheral surface 123, which defines a first engagement portion 124 of the conductive layer 12. The first bonding layer 38 is also in contact with the first upper edge 123A of each first peripheral surface 123. As shown in FIGS. 8 and 9, each first bonding portion 312 has a first upper surface 312A that faces the same side as the mounting surface 121 of the conductive layer 12 in the first direction z. The first bonding layer 38 is in contact with the edge of each first upper surface 312A.

As shown in FIGS. 2 and 5, the second terminal 32 is electrically bonded to the two second electrodes 212 of the first semiconductor element 21 and the two fourth electrodes 222 of the second semiconductor element 22. This electrically connects the second terminal 32 to each second electrode 212 and each fourth electrode 222. Thus, the second terminal 32 is the source terminal of the semiconductor device A10. The second terminal 32 contains copper.

As shown in FIGS. 2 and 5, the second terminal 32 has a second base portion 321, a plurality of second bonding portions 322, and a plurality of third bonding portions 323. As viewed in the first direction z, the second base portion 321 overlaps with the mounting surface 121 of the conductive layer 12. As shown in FIG. 1, the second base portion 321 includes a portion covered with the sealing resin 50 and a portion exposed to the outside from the second side surface 54 of the sealing resin 50. The second bonding portions 322 are connected to the second base portion 321 and are covered with the sealing resin 50. As shown in FIG. 6, the second bonding portions 322 protrude from the second base portion 321 toward the first semiconductor element 21. Each second bonding portion 322 is electrically bonded to a second electrode 212 of the first semiconductor element 21 via a conductive bonding layer 29. The third bonding portions 323 are connected to the second base portion 321 and are covered with the sealing resin 50. The third bonding portions 323 protrude from the second base portion 321 toward the second semiconductor element 22. Each third bonding portion 323 is electrically bonded to a fourth electrode 222 of the second semiconductor element 22 via a conductive bonding layer 29.

As shown in FIG. 1, the first signal terminal 33 includes a portion covered with the sealing resin 50 and a portion exposed to the outside from the second side surface 54 of the sealing resin 50. The first signal terminal 33 is located on one side of the second base portion 321 of the second terminal 32 in the third direction y. The first signal terminal 33 is electrically connected to the first wiring layer 14. Thus, the first signal terminal 33 is electrically connected to the first gate electrode 213 of the first semiconductor element 21 and the second gate electrode 223 of the second semiconductor element 22. In short, the first signal terminal 33 is the gate terminal of the semiconductor device A10. The first signal terminal 33 contains copper. As shown in FIG. 4, the exposed portion of the first signal terminal 33, which protrudes from the second side surface 54, includes a portion extending in the first direction z.

As shown in FIG. 1, the second signal terminal 34 includes a portion covered with the sealing resin 50 and a portion exposed to the outside from the second side surface 54 of the sealing resin 50. The second signal terminal 34 is located between the first signal terminal 33 and the second terminal 32 of the second base portion 321 in the third direction y. In the semiconductor device A10, the second signal terminal 34 is connected to the second base portion 321. Thus, the second signal terminal 34 is electrically connected to each second electrode 212 and each fourth electrode 222. The second signal terminal 34 receives the voltage equal to that applied to the second electrodes 212 and the fourth electrodes 222. The second signal terminal 34 contains copper. Like the exposed portion of the first signal terminal 33, the exposed portion of the second signal terminal 34, which protrudes from the second side surface 54, includes a portion extending in the first direction z.

As shown in FIG. 2, the first conductive member 41 is electrically bonded to the first gate electrode 213 of the first semiconductor element 21 and to the first wiring layer 14. This electrically connects the first wiring layer 14 to the first gate electrode 213. The first conductive member 41 is covered with the sealing resin 50. For example, the first conductive member 41 is a wire that contains either aluminum (Al) or gold (Au).

As shown in FIG. 2, the second conductive member 42 is electrically bonded to the second gate electrode 223 of the second semiconductor element 22 and to the first wiring layer 14. This electrically connects the first wiring layer 14 to the second gate electrode 223. The second conductive member 42 is covered with the sealing resin 50. For example, the second conductive member 42 is a wire that contains either aluminum or gold.

As shown in FIG. 2, the third conductive member 43 is electrically bonded to the first wiring layer 14 and the first signal terminal 33. This electrically connects the first wiring layer 14 to the first signal terminal 33. The third conductive member 43 is covered with the sealing resin 50. For example, the third conductive member 43 is a wire that contains either aluminum or gold. In the semiconductor device A10, the third conductive member 43 is connected to the second conductive member 42.

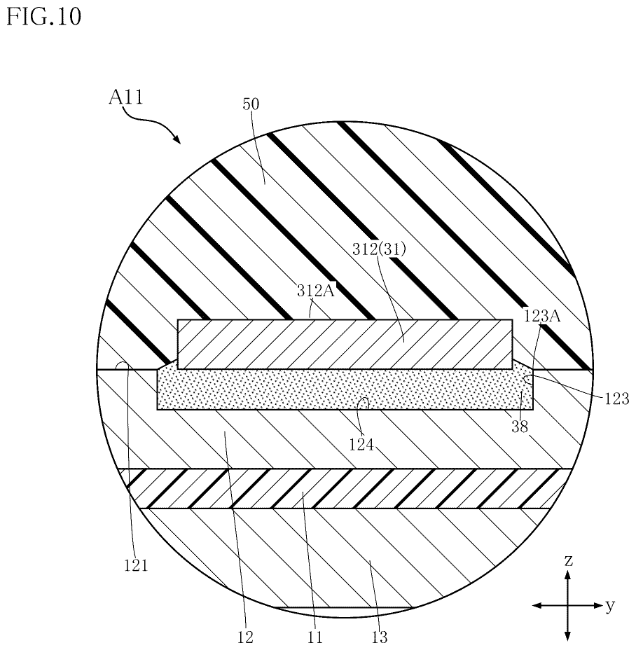

Next, with reference to FIG. 10, the following describes a semiconductor device A11 according to a first variation of the semiconductor device A10. FIG. 10 shows a section taken along the same (or substantially the same line) as the section shown in FIG. 9.

As shown in FIG. 10, the semiconductor device A11 features that each first bonding portion 312 of the first terminal 31 is located outward from the corresponding first engagement portion 124 of the conductive layer 12. The semiconductor device A11 still ensures that the first bonding layer 38 is in contact with the first upper edge 123A of each first peripheral surface 123. The first bonding layer 38 is solder, for example.

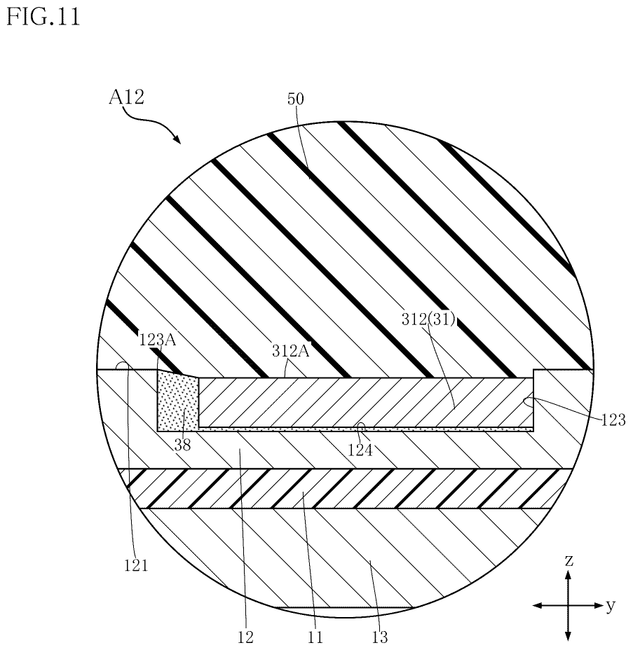

Next, with reference to FIG. 11, the following describes a semiconductor device A12 according to a second variation of the semiconductor device A10. FIG. 11 shows the section taken along the same (or substantially the same line) as the section shown in FIG. 9.

As shown in FIG. 11, the semiconductor device A12 features that the entirety of each first bonding portion 312 of the first terminal 31 is accommodated in the corresponding first engagement portion 124 of the conductive layer 12. In addition, the semiconductor device A12 features that at least one of the first bonding portions 312 is in contact with the first peripheral surface 123 defining the corresponding first engagement portion 124. The semiconductor device A12 still ensures that the first bonding layer 38 is in contact with the first upper edge 123A of each first peripheral surface 123. The first bonding layer 38 is also in contact with the edge of the first upper surface 312A of each first bonding portion 312. The first bonding layer 38 is solder, for example.

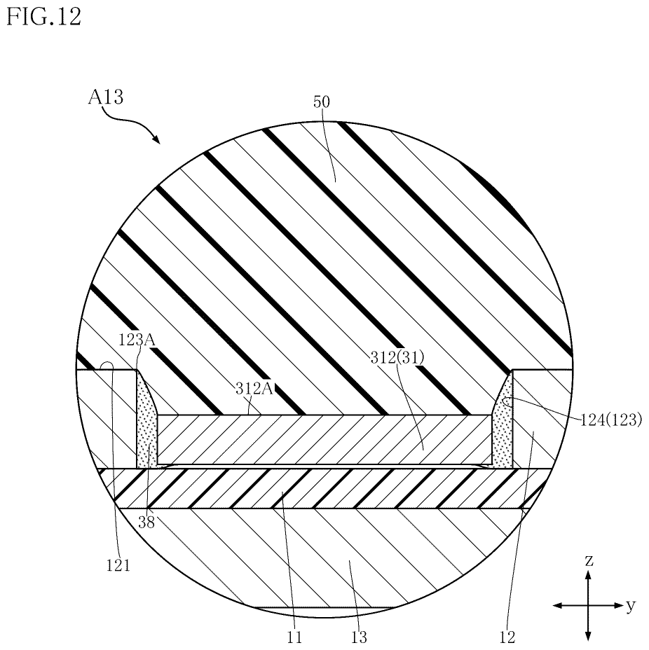

Next, with reference to FIG. 12, the following describes a semiconductor device A13 according to a third variation of the semiconductor device A10. FIG. 12 shows the section taken along the same (or substantially the same line) as the section shown in FIG. 9.

As shown in FIG. 12, the semiconductor device A13 features that the entirety of each first bonding portion 312 of the first terminal 31 is accommodated in the corresponding first engagement portion 124 of the conductive layer 12. In the semiconductor device A13, each first engagement portion 124 is a slit that extends through the conductive layer 12 in the first direction z. The semiconductor device A13 still ensures that the first bonding layer 38 is in contact with the first upper edge 123A of each first peripheral surface 123. The first bonding layer 38 is also in contact with the edge of the first upper surface 312A of each first bonding portion 312. The first bonding layer 38 is solder, for example.

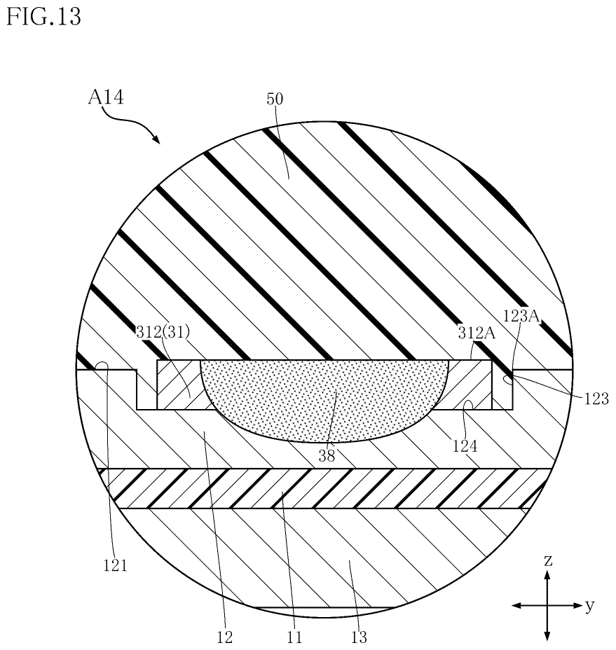

Next, with reference to FIG. 13, the following describes a semiconductor device A14 according to a fourth variation of the semiconductor device A10. FIG. 13 shows the section taken along the same (or substantially the same line) as the section shown in FIG. 9.

The semiconductor device A14 features that each first bonding portion 312 of the first terminal 31 is electrically bonded to a corresponding first engagement portion 124 of the conductive layer 12 by welding, such as laser welding. During welding, a portion of the conductive layer 12 forming a first engagement portion 124 and an adjacent portion of the first bonding portion 312 melt and fuse together into molten metal, which solidifies to forms the weld. In the semiconductor device A14, the solidified molten metal is the first bonding layer 38.

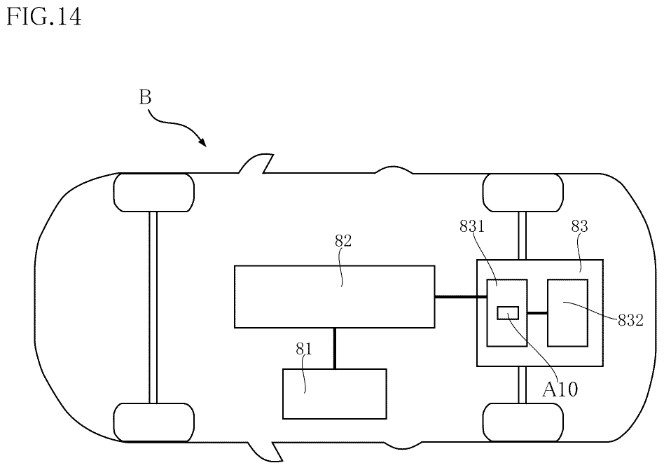

Next, with reference to FIG. 14, the following describes a vehicle B equipped with a semiconductor device A10. The vehicle B is an electric vehicle (EV), for example.

As shown in FIG. 14, the vehicle B includes an on-board charger 81, a storage battery 82, and a drive system 83. The on-board charger 81 is supplied with power wirelessly from an outdoor power supply facility (not shown). In other example, the on-board charger 81 may be supplied with power from an outdoor power supply facility via a wired connection. The on-board charger 81 includes a step-up DC-DC converter. The on-board charger 81 increases the input voltage and supplies the resulting power to the storage battery 82. The voltage is increased to 600 V, for example.

The drive system 83 propels the vehicle B. The drive system 83 includes an inverter 831 and a drive source 832. The semiconductor device A10 forms a part of the inverter 831. The power stored on the storage battery 82 is supplied to the inverter 831. The storage battery 82 supplies DC power to the inverter 831. Unlike the power system shown in FIG. 14, another step-up DC-DC converter may be additionally provided between the storage battery 82 and the inverter 831. The inverter 831 converts DC power to AC power. The inverter 831, which includes the semiconductor device A10, is electrically connected to the drive source 832. The drive source 832 includes an AC motor and a transmission. Supplied with AC power from the inverter 831, the drive source 832 rotates the AC motor, and the rotation is transmitted to the transmission. The transmission reduces the rotational speed transmitted from the AC motor as needed and rotates the axle of the vehicle B. This propels the vehicle B. During operation of the vehicle B, the rotational speed of the AC motor needs to be adjusted based on, for example, the pressed amount of the accelerator pedal. To this end, the inverter 831 of the semiconductor device A10 adjusts the frequency of the AC power to match the rotational speed of the AC motor as needed.

The following describes advantages of the semiconductor device A10.

The semiconductor device A10 includes: a conductive layer 12 having a mounting surface 121; a first semiconductor element 21 bonded to the mounting surface 121; a first terminal 31 electrically connected to the first semiconductor element 21; and a first bonding layer 38 electrically bonding the conductive layer 12 and the first terminal 31. The conductive layer 12 includes a first peripheral surface 123 defining a first engagement portion 124. The first terminal 31 includes a first bonding portion 312 electrically bonded to the first engagement portion 124. The first bonding layer 38 electrically bonds the first engagement portion 124 and the first bonding portion 312. As viewed in the first direction z, the first bonding portion 312 overlaps with the first engagement portion 124. This configuration achieves the following during the process of bonding the first bonding portion 312 to the first engagement portion 124 via the first bonding layer 38. If the first bonding portion 312 shifts in a direction perpendicular to the first direction z, in the case where the first bonding layer 38 is solder, the first bonding layer 38 in a molten state is forced to touch the first peripheral surface 123. In response, the first peripheral surface 123 exerts a reaction force on the molten-state first bonding layer 38 in the direction perpendicular to the first direction z. In short, the self-alignment effect is achieved on the first bonding portion 312 by the molten-state first bonding layer 38. Due to the self-alignment effect, the first bonding portion 312 automatically positions itself on the position overlapping with the first engagement portion 124 as viewed in the first direction z. The configuration of the semiconductor device A10 described above thus prevents or reduces misalignment of the terminal with the conductive layer 12.

For achieving a stronger self-alignment effect, it is preferable for the first bonding layer 38 to be in contact with the first peripheral surface 123 of the conductive layer 12. This configuration implies that the first peripheral surface 123 exerts a greater reaction force on the molten-state first bonding layer 38. More preferably, the first bonding layer 38 is in contact with the first upper edge 123A of the first peripheral surface 123 of the conductive layer 12. This ensures that the molten-state first bonding layer 38 produces greater surface tension.

In the semiconductor device A10, at least a portion of the first bonding portion 312 of the first terminal 31 is accommodated in the first engagement portion 124. This configuration ensures that the first peripheral surface 123 of the conductive layer 12 exerts a greater reaction force on the molten-state first bonding layer 38, thereby preventing or reducing misalignment of the first bonding portion 312 more efficiently. This configuration thus efficiently prevents or reduces misalignment of the first terminal 31 with the conductive layer 12, and also prevents rotation of the first terminal 31 around the axis in the first direction z.

The first bonding portion 312 of the first terminal 31 has the first upper surface 312A that faces the same side as the mounting surface 121 of the conductive layer 12 in the first direction z. The first bonding layer 38 is in contact with the edge of the first upper surface 312A. This configuration ensures that the molten-state first bonding layer 38 produces greater surface tension, thereby achieving the self-alignment effect more efficiently.

The semiconductor device A10 further includes: an insulating layer 11 bonded to the conductive layer 12; and a heat dissipation layer 13 that is located on the opposite side of the insulating layer 11 from the conductive layer 12 and is bonded to the insulating layer 11. The insulating layer 11 and the conductive layer 12 are covered with the sealing resin 50. The heat dissipation layer 13 is exposed to the outside from the sealing resin 50. This configuration prevents a decrease in the dielectric strength and improves the heat dissipation of the semiconductor device A10.

As viewed in the first direction z, the conductive layer 12 and the heat dissipation layer 13 are each spaced apart from the periphery 111 of the insulating layer 11. With this configuration, the sealing resin 50 sandwiches the periphery 111 and its adjacent portion of the insulating layer 11 from both sides in the first direction z. This is effective for preventing delamination of the insulating layer 11 and the conductive layer 12 from the sealing resin 50.

The dimension of each of the conductive layer 12 and the heat dissipation layer 13 in the first direction z is larger than the dimension of the insulating layer 11 in the first direction z. This configuration is effective for reducing the thermal resistance of the conductive layer 12 and the heat dissipation layer 13 in the first direction z. The heat dissipation of the semiconductor device A10 is thus improved.

### Second Embodiment

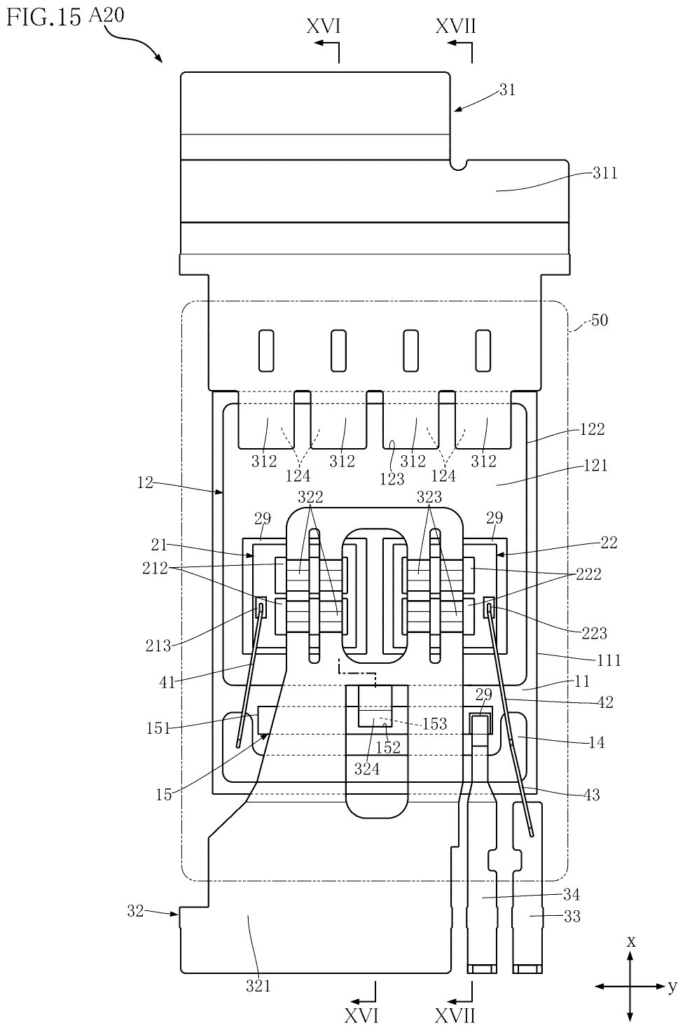

With reference to FIGS. 15 to 19, the following describes a semiconductor device A20 according to a second embodiment of the present disclosure. In these figures, elements that are identical or similar to those of the semiconductor device A10 described above are denoted by the same reference numerals, and redundant descriptions are omitted. For convenience, FIG. 15 shows the sealing resin 50 as transparent. The outline of the sealing resin 50 is indicated by imaginary lines in FIG. 15.

Compared to the semiconductor device A10, the semiconductor device A20 additionally includes a second wiring layer 15 and a second bonding layer 39 and differs in the configurations of the second terminal 32 and the second signal terminal 34.

As shown in FIGS. 15 to 17, the second wiring layer 15 is located on the same side as the conductive layer 12 with respect to the insulating layer 11 and is bonded to the insulating layer 11. The second wiring layer 15 is located between the conductive layer 12 and the first wiring layer 14 in the second direction x. The second wiring layer 15 extends in the third direction y. As viewed in the first direction z, the second wiring layer 15 is enclosed within the periphery 111 of the insulating layer 11. The second wiring layer 15 is covered with the sealing resin 50. The second wiring layer 15 contains copper. The dimension of the second wiring layer 15 in the first direction z is larger than the dimension of the insulating layer 11 in the first direction z.

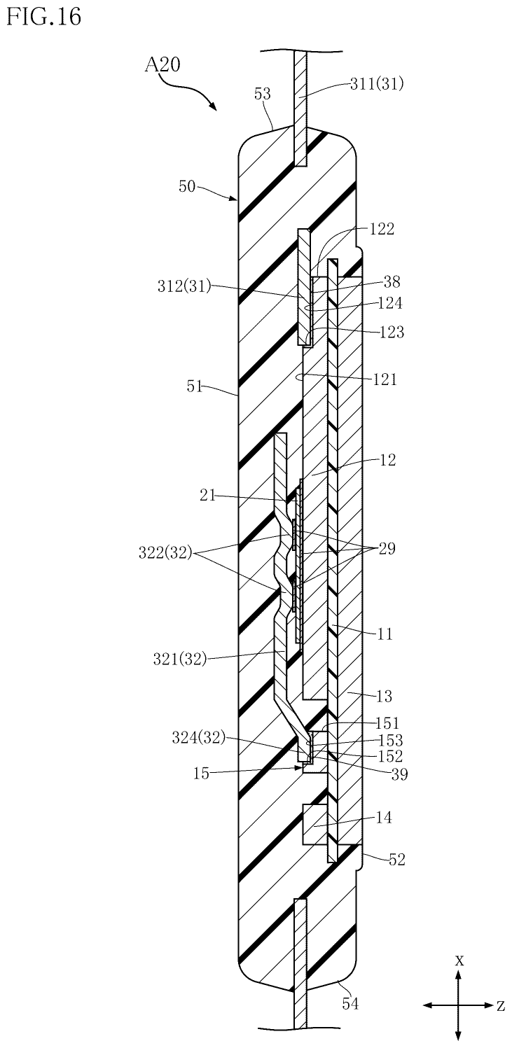

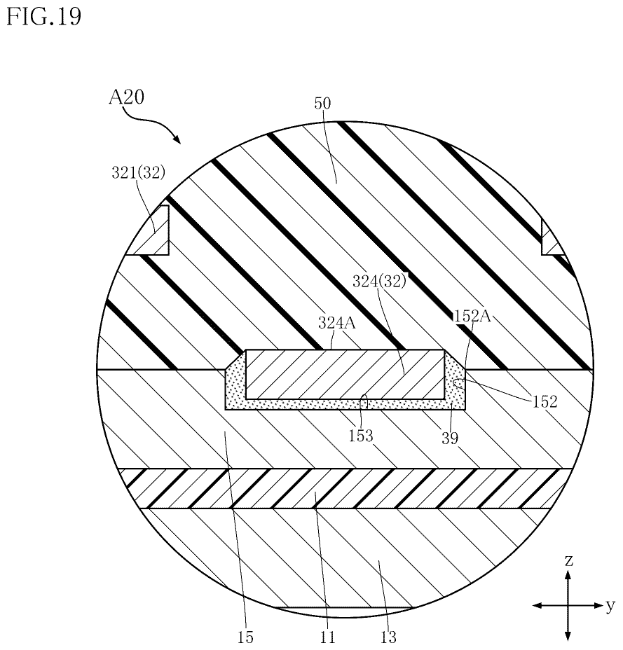

As shown in FIGS. 15 and 16, the second wiring layer 15 has a second end surface 151 and a second peripheral surface 152. The second end surface 151 faces in a direction perpendicular to the first direction z. The second peripheral surface 152 faces in a direction perpendicular to the first direction z and is located inward of the second wiring layer 15 from the second end surface 151 as viewed in the first direction z. As shown in FIG. 19, the second peripheral surface 152 has a second upper edge 152A. The second upper edge 152A is a boundary between the second peripheral surface 152 and the surface of the second wiring layer 15 facing the same side as the mounting surface 121 of the conductive layer 12 in the first direction z.

As shown in FIGS. 16 and 19, the second wiring layer 15 has a second engagement portion 153. The second engagement portion 153 is defined by the second peripheral surface 152. The second engagement portion 153 is a recess that is recessed in the first direction z.

As shown in FIGS. 15 and 16, the second terminal 32 has a supporting portion 324. The supporting portion 324 is connected to the second base portion 321 of the second terminal 32. The supporting portion 324 is covered with the sealing resin 50. In the third direction y, the supporting portion 324 is located between the second bonding portions 322 of the second terminal 32 and the third bonding portions 323 of the second terminal 32. As shown in FIG. 19, at least a portion of the supporting portion 324 is accommodated in the second engagement portion 153 of the second wiring layer 15.

As shown in FIG. 19, the second bonding layer 39 electrically bonds the second engagement portion 153 of the second wiring layer 15 and the supporting portion 324 of the second terminal 32. This electrically connects the second wiring layer 15 to each of the two second electrodes 212 of the first semiconductor element 21 and each of the two fourth electrodes 222 of the second semiconductor element 22. The second bonding layer 39 is solder, for example.

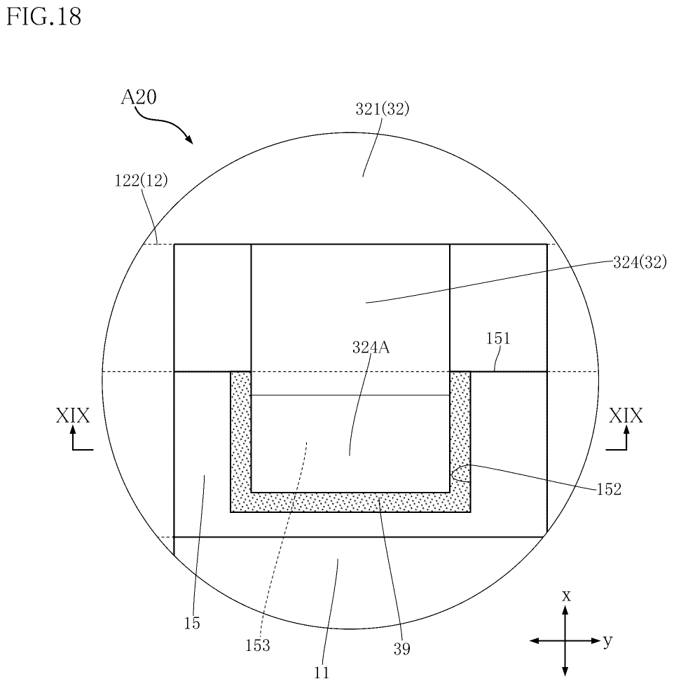

As shown in FIG. 19, the second bonding layer 39 is in contact with the second peripheral surface 152, which defines the second engagement portion 153 of the second wiring layer 15. The second bonding layer 39 is also in contact with the second upper edge 152A of the second peripheral surface 152. As shown in FIGS. 18 and 19, the supporting portion 324 of the second terminal 32 has an second upper surface 324A that faces the same side as the mounting surface 121 of the conductive layer 12 in the first direction z. The second bonding layer 39 is in contact with the edge of the second upper surface 324A.

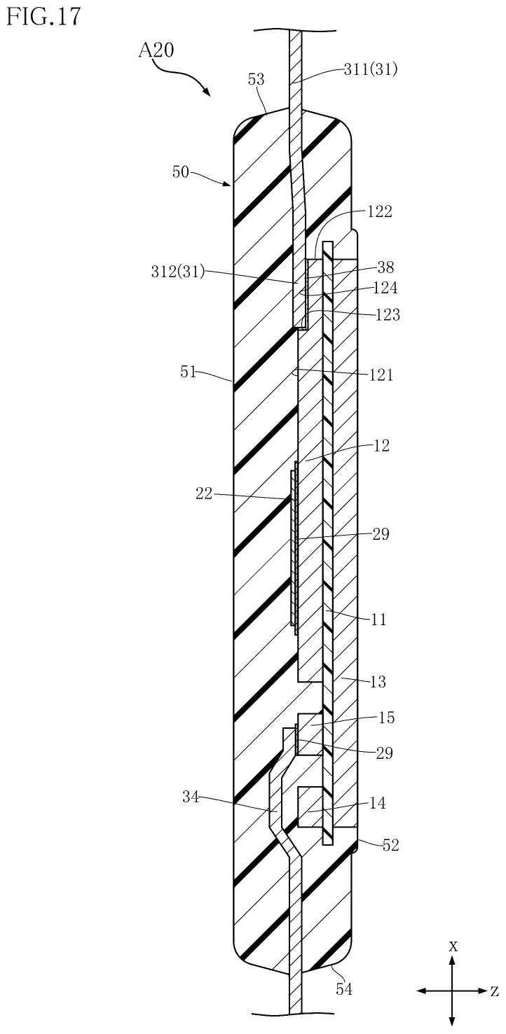

As shown in FIG. 15, the second signal terminal 34 is spaced apart from the second terminal 32. As shown in FIGS. 15 and 17, the second signal terminal 34 is electrically bonded to the second wiring layer 15 via a conductive bonding layer 29. This electrically connects the second signal terminal 34 to the second wiring layer 15.

The following describes advantages of the semiconductor device A20.

The semiconductor device A20 includes: a conductive layer 12 having a mounting surface 121; a first semiconductor element 21 bonded to the mounting surface 121; a first terminal 31 electrically connected to the first semiconductor element 21; and a first bonding layer 38 electrically bonding the conductive layer 12 and the first terminal 31. The conductive layer 12 includes a first peripheral surface 123 defining a first engagement portion 124. The first terminal 31 includes a first bonding portion 312 electrically bonded to the first engagement portion 124. The first bonding layer 38 electrically bonds the first engagement portion 124 and the first bonding portion 312. As viewed in the first direction z, the first bonding portion 312 overlaps with the first engagement portion 124. The configuration of the semiconductor device A20 described above thus prevents or reduces misalignment of the terminal with the conductive layer 12. Additionally, the semiconductor device A20 has a configuration in common with the semiconductor device A10, thereby achieving the same effect as the semiconductor device A10.

The semiconductor device A20 further includes a second wiring layer 15, and a second bonding layer 39 electrically bonding the second wiring layer 15 and the second terminal 32. The second wiring layer 15 includes a second peripheral surface 152 defining a second engagement portion 153. The second terminal 32 has a supporting portion 324 that is electrically bonded to the second engagement portion 153 via a second bonding layer 39. The second bonding layer 39 is in contact with the edge of the second peripheral surface 152. At least a portion of the supporting portion 324 is accommodated in the second engagement portion 153. This configuration achieves the following during the process of electrically bonding the supporting portion 324 to the second engagement portion 153 via the second bonding layer 39. If the supporting portion 324 shifts in a direction perpendicular to the first direction z, the second peripheral surface 152 exerts a reaction force on the molten-state second bonding layer 39 in the direction perpendicular to the first direction z. Then, misalignment of the supporting portion 324 is prevented or reduced by the second peripheral surface 152. This configuration thus efficiently prevents or reduces misalignment of the second terminal 32 with the second wiring layer 15, and also prevents rotation of the second terminal 32 around the axis in the first direction z.

The supporting portion 324 of the second terminal 32 is connected to the second base portion 321 of the second terminal 32. The supporting portion 324 is located between the second bonding portions 322 and the third bonding portions 323 of the second terminal 32 in a direction perpendicular to the first direction z. This configuration can make the conduction path length from a fourth electrode 222 of the second semiconductor element 22 to the second wiring layer 15 closer to the conduction path length from a second electrode 212 of the first semiconductor element 21 to the second wiring layer 15. This consequently ensures that the conduction path length from the second signal terminal 34 to the fourth electrode 222 is substantially equal to the conduction path length from the second signal terminal 34 to the second electrode 212. This helps prevent resonance phenomena due to vibrations of the first semiconductor element 21 and the second semiconductor element 22 during operation.

The present disclosure is not limited to the embodiments described above. Various design changes may be made to the specific configuration of each part of the present disclosure.

The present disclosure includes embodiments described in the following clauses.

### Clause 1.

A semiconductor device comprising:
a conductive layer including a mounting surface facing in a first direction;
a first semiconductor element bonded to the mounting surface;
a first terminal electrically connected to the first semiconductor element; and
a first bonding layer electrically bonding the conductive layer and the first terminal,
wherein the conductive layer includes:
   a first end surface facing in a direction perpendicular to the first direction; and
   a first peripheral surface facing in a direction perpendicular to the first direction and located inward of the conductive layer from the first end surface as viewed in the first direction,
the conductive layer includes a first engagement portion defined by the first peripheral surface,
the first terminal includes a first bonding portion electrically bonded to the first engagement portion via the first bonding layer, and
the first bonding portion overlaps with the first engagement portion as viewed in the first direction.

### Clause 2.

The semiconductor device according to Clause 1, wherein at least a portion of the first bonding portion is accommodated in the first engagement portion, and
the first bonding layer is in contact with the first peripheral surface.

### Clause 3.

The semiconductor device according to Clause 2, wherein the first terminal includes a first base portion that is spaced apart from the mounting surface as viewed in the first direction, and
as viewed in the first direction, the first bonding portion extends from the first base portion toward the first semiconductor element in a direction perpendicular to the first direction.

### Clause 4.

The semiconductor device according to Clause 3, wherein the first bonding portion includes a first upper surface facing a same side as the mounting surface in the first direction, and
the first bonding layer is in contact with an edge of the first upper surface.

### Clause 5.

The semiconductor device according to Clause 3 or 4, wherein the first bonding portion is in contact with the first peripheral surface.

### Clause 6.

The semiconductor device according to Clause 3 or 4, wherein the first engagement portion includes a recess that is recessed from the mounting surface.

### Clause 7.

The semiconductor device according to Clause 3 or 4, wherein the first engagement portion includes a slit that extends through the conductive layer.

### Clause 8.

The semiconductor device according to Clause 3 or 4, wherein the first semiconductor element includes a first electrode and a second electrode that are located on opposite sides in the first direction, and
the first electrode is electrically bonded to the mounting surface.

### Clause 9.

The semiconductor device according to Clause 8, further comprising a second terminal electrically bonded to the second electrode.

### Clause 10.

The semiconductor device according to Clause 9, further comprising a first wiring layer,
wherein the first semiconductor element includes a first gate electrode located on the same side as the second electrode in the first direction, and
the first wiring layer is electrically connected to the first gate electrode.

### Clause 11.

The semiconductor device according to Clause 10, further comprising:
a first signal terminal electrically connected to the first wiring layer; and
a sealing resin covering the first semiconductor element,
wherein the first base portion and the first signal terminal each include a portion exposed to outside from the sealing resin.

### Clause 12.

The semiconductor device according to Clause 11, further comprising an insulating layer,
wherein the conductive layer and the first wiring layer are bonded to a surface of the insulating layer facing a side that the mounting surface faces in the first direction, and
the conductive layer and the first wiring layer are each spaced apart from a periphery of the insulating layer as viewed in the first direction.

### Clause 13.

The semiconductor device according to Clause 12, further comprising a heat dissipation layer that is located on an opposite side of the insulating layer from the conductive layer and is bonded to the insulating layer,
wherein the heat dissipation layer is spaced apart from the periphery of the insulating layer as viewed in the first direction,
the insulating layer and the conductive layer are covered with the sealing resin, and
the heat dissipation layer is exposed to outside from the sealing resin.

### Clause 14.

The semiconductor device according to Clause 13, wherein a dimension of each of the conductive layer and the heat dissipation layer in the first direction is larger than a dimension of the insulating layer in the first direction.

### Clause 15.

The semiconductor device according to Clause 11, further comprising:
a second wiring layer; and
a second bonding layer electrically bonding the second wiring layer and the second terminal,
wherein the second wiring layer includes:
   a second end surface facing in a direction perpendicular to the first direction; and
   a second peripheral surface facing in a direction perpendicular to the first direction and located inward of the second wiring layer from the second peripheral surface as viewed in the first direction,
the second wiring layer includes a second engagement portion defined by the second peripheral surface,
the second terminal includes a supporting portion electrically bonded to the second engagement portion via the second bonding layer,
the second bonding layer is in contact with the second peripheral surface, and
at least a portion of the supporting portion is accommodated in the second engagement portion.

### Clause 16.

The semiconductor device according to Clause 15, further comprising a second semiconductor element including a third electrode and a fourth electrode that are located on opposite sides in the first direction, the second semiconductor element being covered with the sealing resin,
the third electrode is electrically bonded to the mounting surface,
the second terminal includes:
   a second base portion including a portion exposed to outside from the sealing resin;
   a second bonding portion connected to the second base portion and electrically bonded to the second electrode; and
   a third bonding portion connected to the second base portion and electrically bonded to the fourth electrode,
the supporting portion is connected to the second base portion, and
the supporting portion is located between the second bonding portion and the third bonding portion in a direction perpendicular to the first direction.

### Clause 17.

The semiconductor device according to Clause 16, further comprising a second signal terminal electrically connected to the second wiring layer,
wherein the second signal terminal includes a portion exposed to outside from the sealing resin.

### Clause 18.

A vehicle comprising:
a drive source; and
the semiconductor device according to Clause 11,
wherein the semiconductor device is electrically connected to the drive source.

REFERENCE NUMERALS

| | |
|---|---|
| A10, A20: semiconductor element | 11: insulating layer |
| 111: periphery | 12: conductive layer |
| 121: mounting surface | 122: first end surface |
| 123: first peripheral surface | 123A: first upper edge |
| 124: first engagement portion | 13: heat dissipation layer |
| 14: first wiring layer | 15: second wiring layer |
| 151: second end surface | 152: second peripheral surface |
| 152A: second upper edge | 153: second engagement portion |
| 21: first semiconductor element | 211: first electrode |
| 212: second electrode | 213: first gate electrode |
| 22: second semiconductor element | 221: third electrode |
| 222: fourth electrode | 223: second gate electrode |
| 29: conductive bonding layer | 31: first terminal |
| 311: first base portion | 312: first bonding portion |
| 312A: first upper surface | 32: second terminal |
| 321: second base portion | 322: second bonding portion |
| 323: third bonding portion | 324: supporting portion |
| 324A: second upper surface | 33: first signal terminal |
| 34: second signal terminal | 38: first bonding layer |
| 39: second bonding layer | 41: first conductive member |
| 42: second conductive member | 43: third conductive member |
| 50: sealing resin | 51: top surface |
| 52: bottom surface | 53: first side surface |
| 54: second side surface | 81: on-board charger |
| 82: storage battery | 83: drive system |
| 831: inverter | 832: drive source |
| z: first direction | x: second direction |
| y: third direction | |

1. A semiconductor device comprising:
a conductive layer including a mounting surface facing in a first direction;
a first semiconductor element bonded to the mounting surface;
a first terminal electrically connected to the first semiconductor element; and
a first bonding layer electrically bonding the conductive layer and the first terminal,
wherein the conductive layer includes:
a first end surface facing in a direction perpendicular to the first direction; and
a first peripheral surface facing in a direction perpendicular to the first direction and located inward of the conductive layer from the first end surface as viewed in the first direction,
the conductive layer includes a first engagement portion defined by the first peripheral surface,
the first terminal includes a first bonding portion electrically bonded to the first engagement portion via the first bonding layer, and
the first bonding portion overlaps with the first engagement portion as viewed in the first direction.

2. The semiconductor device according to claim 1, wherein at least a portion of the first bonding portion is accommodated in the first engagement portion, and
the first bonding layer is in contact with the first peripheral surface.

3. The semiconductor device according to claim 2, wherein the first terminal includes a first base portion that is spaced apart from the mounting surface as viewed in the first direction, and
as viewed in the first direction, the first bonding portion extends from the first base portion toward the first semiconductor element in a direction perpendicular to the first direction.

4. The semiconductor device according to claim 3, wherein the first bonding portion includes a first upper surface facing a same side as the mounting surface in the first direction, and
the first bonding layer is in contact with an edge of the first upper surface.

5. The semiconductor device according to claim 3, wherein the first bonding portion is in contact with the first peripheral surface.

6. The semiconductor device according to claim 3, wherein the first engagement portion includes a recess that is recessed from the mounting surface.

7. The semiconductor device according to claim 3, wherein the first engagement portion includes a slit that extends through the conductive layer.

8. The semiconductor device according to claim 3, wherein the first semiconductor element includes a first electrode and a second electrode that are located on opposite sides in the first direction, and
the first electrode is electrically bonded to the mounting surface.

9. The semiconductor device according to claim 8, further comprising a second terminal electrically bonded to the second electrode.

10. The semiconductor device according to claim 9, further comprising a first wiring layer,
wherein the first semiconductor element includes a first gate electrode located on the same side as the second electrode in the first direction, and
the first wiring layer is electrically connected to the first gate electrode.

11. The semiconductor device according to claim 10, further comprising:
a first signal terminal electrically connected to the first wiring layer; and
a sealing resin covering the first semiconductor element,
wherein the first base portion and the first signal terminal each include a portion exposed to outside from the sealing resin.

12. The semiconductor device according to claim 11, further comprising an insulating layer,
wherein the conductive layer and the first wiring layer are bonded to a surface of the insulating layer facing a side that the mounting surface faces in the first direction, and
the conductive layer and the first wiring layer are each spaced apart from a periphery of the insulating layer as viewed in the first direction.

13. The semiconductor device according to claim 12, further comprising a heat dissipation layer that is located on an opposite side of the insulating layer from the conductive layer and is bonded to the insulating layer,
wherein the heat dissipation layer is spaced apart from the periphery of the insulating layer as viewed in the first direction,
the insulating layer and the conductive layer are covered with the sealing resin, and
the heat dissipation layer is exposed to outside from the sealing resin.

14. The semiconductor device according to claim 13, wherein a dimension of each of the conductive layer and the heat dissipation layer in the first direction is larger than a dimension of the insulating layer in the first direction.

15. The semiconductor device according to claim 11, further comprising:
a second wiring layer; and
a second bonding layer electrically bonding the second wiring layer and the second terminal,
wherein the second wiring layer includes:
a second end surface facing in a direction perpendicular to the first direction; and
a second peripheral surface facing in a direction perpendicular to the first direction and located inward of the second wiring layer from the second peripheral surface as viewed in the first direction,
the second wiring layer includes a second engagement portion defined by the second peripheral surface,
the second terminal includes a supporting portion electrically bonded to the second engagement portion via the second bonding layer,
the second bonding layer is in contact with the second peripheral surface, and
at least a portion of the supporting portion is accommodated in the second engagement portion.

16. The semiconductor device according to claim 15, further comprising a second semiconductor element including a third electrode and a fourth electrode that are located on opposite sides in the first direction, the second semiconductor element being covered with the sealing resin,
the third electrode is electrically bonded to the mounting surface,
the second terminal includes:
a second base portion including a portion exposed to outside from the sealing resin;
a second bonding portion connected to the second base portion and electrically bonded to the second electrode; and
a third bonding portion connected to the second base portion and electrically bonded to the fourth electrode,
the supporting portion is connected to the second base portion, and
the supporting portion is located between the second bonding portion and the third bonding portion in a direction perpendicular to the first direction.

17. The semiconductor device according to claim 16, further comprising a second signal terminal electrically connected to the second wiring layer,
wherein the second signal terminal includes a portion exposed to outside from the sealing resin.

18. A vehicle comprising:
a drive source; and
the semiconductor device according to claim 11,
wherein the semiconductor device is electrically connected to the drive source.
